(19) United States
(12) Patent Application Publication
(10) Pub. No.: US 2011/0240109 A1
(43) Pub. Date: Oct. 6, 2011

(54) TANDEM SOLAR CELL MADE OF CRYSTALLINE SILICON AND CRYSTALLINE SILICON CARBIDE AND METHOD FOR PRODUCTION THEREOF

(75) Inventors: Stefan Janz, Freiburg (DE); Stefan Reber, Gundelfingen (DE)

(73) Assignee: FRAUNHOFER-GESELLSCHAFT ZUR FORDERUNG DER ANGEWANDTEN FORSCHUNG E.V.

(21) Appl. No.: 13/127,414

(22) PCT Filed: Nov. 17, 2009
(86) PCT No.: PCT/EP09/08163

§ 371 Date: Jun. 16, 2011

(30) Foreign Application Priority Data
Nov. 24, 2008 (DE) 08 020 398.7

(51) Int. Cl. H01L 31/06; H01L 31/18

(52) U.S. Cl. 136/255; 438/57; 257/E31.001

(57) ABSTRACT

The invention describes photovoltaic tandem solar cells made of crystalline silicon and crystalline silicon carbide having an Si/C intermediate layer. Furthermore, the invention describes a method for the production of tandem solar cells.

The invention describes photovoltaic tandem solar cells made of crystalline silicon and crystalline silicon carbide having an Si/C intermediate layer. Furthermore, the invention describes a method for the production of tandem solar cells.

Solar cells are known from prior art. The photovoltaics market worldwide is dominated at present by wafer solar cells made of crystalline silicon. Since the technological development of this concept has already progressed very widely, the theoretically possible maximum efficiency in the case of experimental solar cells is already up to approx. 90%. In the case of Si wafer solar cells manufactured industrially on a large scale, it is attempted, by means of scaling and adaptation of the technologies used for this purpose, to approximate to this best efficiency.

U.S. Pat. No. 5,057,163 describes a thin-film solar cell made of polycrystalline silicon on a ceramic material having a reflective layer. By using a photoactive layer, as in the example described in the disclosure, the spectral range of the incident light can be used only partially for energy production.

In U.S. Pat. No. 4,419,533, a photovoltaic device comprising various types of semiconductor compounds and a reflector layer which beams back an unspecific part of the incident light is disclosed.

The solar cells known from the state of the art comprise inter alfa amorphous silicon and hence have a higher degree of disorder in their crystal structure. When using only one photovoltaic layer, a smaller proportion of the light can consequently be converted into energy and hence only a lower efficiency can be achieved.

Starting herefrom, it is the object of the present invention to eliminate the disadvantages of the state of the art and to provide a photovoltaic tandem solar cell and also a method for the production thereof so that, due to the structure comprising a plurality of layers, a greater proportion of the spectral range can be used for energy production and a high degree of crystal order is provided by the ordered structure of the layers, which crystal arrangement increases in addition the achievable efficiency.

This object is achieved by the photovoltaic tandem cell having the features of claim 1. Claim 15 concerns a method for the production of photovoltaic tandem cells. Further advantageous embodiments are contained in the dependent claims 2 to 14.

The invention comprises a photovoltaic tandem cell having at least two photoactive layers, consisting of respectively one n-doped emitter and one p-doped region and at least one intermediate layer, the at least one first photoactive layer comprising silicon carbide and the at least one second photoactive layer silicon or consisting thereof and the at least one intermediate layer being an Si/C mixed layer. The first photoactive layer is thereby the front-side orientated towards the light and the second photoactive layer forms the rear-side of the photovoltaic cell and hence the side orientated towards the substrate. It is thereby essential that at least the n-doped emitter and/or the p-doped region of at least one layer has been deposited epitaxially.

The structure of at least two photoactive layers enables better exploitation of the spectral range of sunlight. As a function of the spacing between the energy levels, the wavelengths corresponding to this energy are absorbed. Since here at least two different photolayers are comprised, which layers have different energy spacings because of their chemical composition and hence absorb light in different wavelength ranges, a greater spectral range is thus used for energy production.

In a preferred embodiment, the photovoltaic tandem cell is monolithic. This construction produces higher stability of the solar cell and also a structure which has a low number of faulty cells.

Preferably, the first photoactive layer which is a silicon carbide layer has a thickness of at most 40 μm. It applies for this layer thickness that the incident light of a suitable wavelength can be absorbed well and also radiation through the layer is possible. Basically, the first layer could also consist of two or more layers made of SiC.

The central element of the present invention is that at least one Si/C mixed layer which has a lattice adaptation to the photoactive layers due to an adapted Si/C ratio is present between the two photoactive layers.

Adaptation of the Si/C ratio of the Si/C mixed layer is effected by the reduction in the silicon content and the increase, directly proportional thereto, in the carbon content as a function of the thickness of the intermediate layer. The reduction in the silicon content is effected in the direction from the silicon layer to the silicon carbide layer. Thus tensions in the structure are reduced and the number of displacements in the Si/C crystal is minimised. The lattice adaptation to the photoactive layers hence enables high energy production due to optimal exploitation of the incident light.

The thickness of the intermediate layer is favourably at most 10 μm. Thus, a lattice adaptation is made possible, on the one hand, and, on the other hand, this layer thickness can be radiated through so that the light loss can be kept as low as possible.

The invention of course also comprises embodiments of the photovoltaic tandem cell in which the intermediate layer consists of two Si/C mixed layers. This facilitates the processing during the production process.

Preferably, a silicon layer deposited on a monocrystalline silicon wafer or a silicon wafer suitable for a solar cell is used as substrate. These have a high degree of order.

In a preferred embodiment of the photovoltaic tandem cell, the thickness of the at least one photovoltaic layer which consists of Si is at most 50 μm. Hence, both the absorption of light with a suitable wavelength range is ensured and a specific stability of the tandem solar cell is obtained. Also the Si layer can be formed by two or more individual layers.

Preferably, at least the highly doped emitter of a first and/or second photoactive layer was formed epitaxially by means of vapour-phase deposition. Thus, high uniformity of the doping and also of the deposited layer is obtained. The number of undesired faulty points in the crystal is consequently small. Furthermore, a particularly stable layer sequence is obtained by this type of application.

In a further preferred embodiment, the intermediate layer was foiiiied by means of rapid thermal vapour-phase deposition in a temperature range of 800 to 1,400° C. and a pressure range of 1 mbar to 1 bar. In this temperature and pressure range, an optimal result is made possible.

The layer consisting of silicon carbide is preferably formed by means of vapour-phase deposition in a temperature range of 800 to 1,400° C. and a pressure range of 1 mbar to 1 bar. Thus the layer thickness and the structure of the silicon carbide layer can be tracked and controlled very precisely.

In a further preferred embodiment, the photovoltaic tandem cell was contacted electrically on the front- and rear-side. This form of contacting represents substantial simplification technologically since the processing duration is accelerated as a result of a lower number of contact- or soldering places.

In an alternative embodiment, the photoactive layers were wired preferably individually. The intermediate layer here serves exclusively for equalising both lattice constants. These two solar cells are not connected to each other electrically via the Si/C intermediate layer.

The invention also makes available a method for the production of a photovoltaic tandem cell, as described, which is characterised in that at least the n-doped emitter and/or the p-doped region of at least one layer is deposited by means of an epitaxial process. Thus a silicon/silicon carbide tandem thin-film solar cell is obtained, which has both high stability and significantly higher efficiency in comparison with solar cells which have only one photoactive layer.

The described layer structure can also be of interest for sensors or Si-based light diodes.

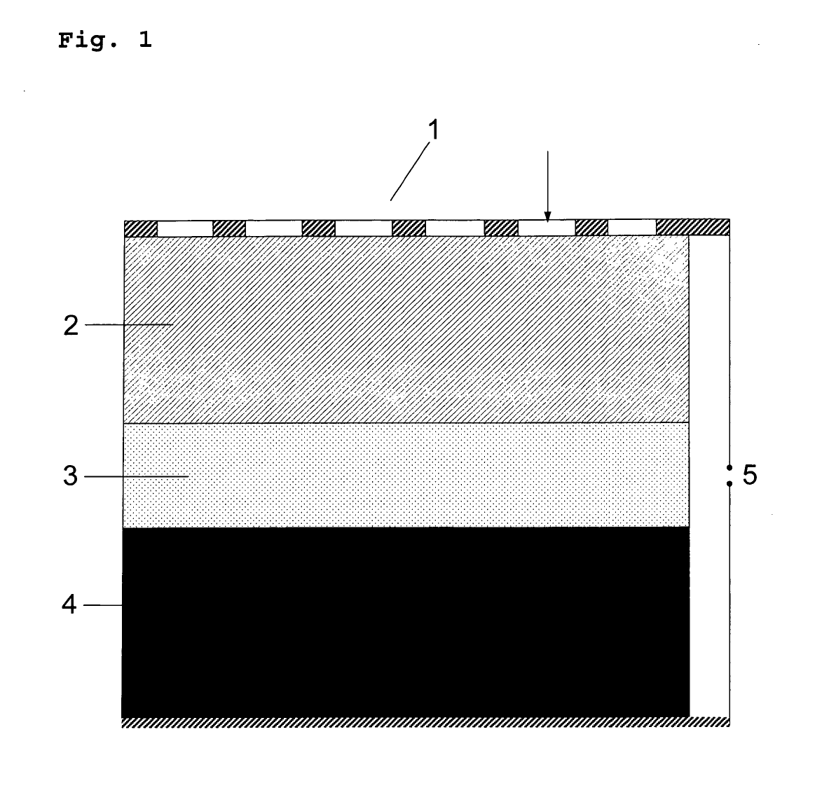

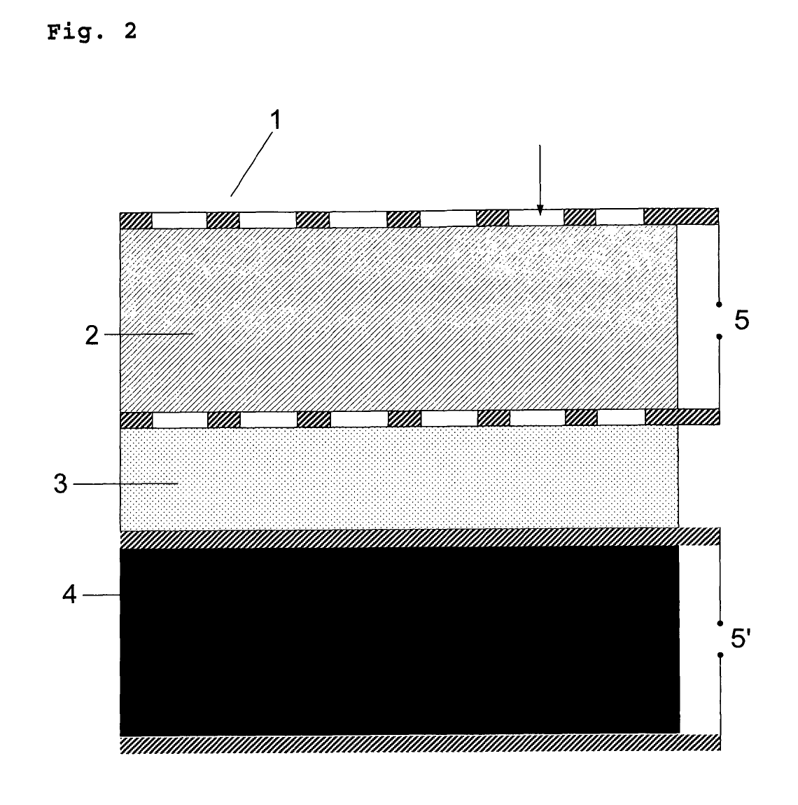

The subject according to the application is intended to be explained in more detail with reference to the following FIGS. 1 to 2 and embodiments 1 to 2 without wishing to restrict said subject to the variants mentioned here.

FIG. 1 shows a monolithically wired tandem solar cell.

FIG. 2 shows a tandem solar cell with individual wiring.

In FIG. 1, a monolithically wired tandem solar cell 1 made of crystalline silicon 4 and crystalline silicon carbide 2 is represented, which is connected by the crystalline Si/C intermediate layer 3. It is provided with electrical contacts 5 on the front- and rear-side. The arrow characterises the front-side to be irradiated. The thickness of the layer 2 is at least 5 μm and that of the layer 4 at least 10 μm. The Si/C mixed layer has a thickness of less than 1 μm.

FIG. 2 shows the individual wiring of a tandem solar cell 1 analogously to FIG. 1. This has a layer made of crystalline silicon carbide 2. It is connected via the Si/C intermediate layer 3 to the crystalline silicon carbide layer 4. Both photoactive regions here are contacted electrically individually 5, 5′. The arrow points towards the front-side of the photovoltaic tandem solar cell orientated towards the sunlight.

### EXAMPLE 1

Both materials are grown epitaxially with the help of vapour-phase deposition (CVD), e.g. from chlorosilanes. The starting substrate is an n-doped emitter layer deposited on a p-doped silicon wafer 4. The emitter layer has a thickness of 2 μm. The intermediate layer 3 consists of two very thin, highly doped (p⁺⁺/n⁺⁺) Si/C mixed layers which are significantly smaller than 1 μm and grown by means of RTCVD (rapid thermal chemical vapour deposition). The base of the SiC cell 2 and subsequently the emitter (n⁺) are in turn grown by means of CVD. The tandem solar cell 1 is contacted electrically 5 on the front-side and rear-side (monolithic wiring).

### EXAMPLE 2

The starting substrate is a silicon wafer 4 suitable for a solar cell. The intermediate layer 3 is formed by means of rapid thermal vapour-phase deposition in a temperature range of 800 to 1,400° C. and a pressure range of 1 mbar to 1 bar. Following thereon, the base of the silicon carbide cell (p) 2 and subsequently the emitter (n⁺) are grown by means of CVD (thermal vapour-phase deposition). This is effected in a pressure range of 1 mbar to 1 bar and in a temperature range of 800 to 1,400° C. The contacting of the tandem solar cell 1 is effected via the individual wiring 5, 5′ of the silicon carbide layer 2 and of the silicon layer 4 (mechanical stacking).

1. A photovoltaic tandem cell having at least two photoactive layers, consisting of respectively one n-doped emitter and one p-doped region and at least one intermediate layer, wherein the at least one first photoactive layer comprises silicon carbide and the at least one second photoactive layer silicon or consists thereof and the intermediate layer is at least one Si/C mixed layer, the at least one first photoactive layer representing the front-side orientated towards the light and the at least one second photoactive layer the rear-side of the photovoltaic cell and hence the side orientated towards the substrate, and in that at least the n-doped emitter and/or the p-doped region of at least one layer was deposited epitaxially.

2. The photovoltaic tandem cell according to claim 1, wherein the photovoltaic tandem cell is monolithic.

3. The photovoltaic tandem cell according to claim 1, wherein the thickness of the first photoactive layer is at most 40 μm.

4. The photovoltaic tandem cell according to claim 1, wherein the at least one Si/C mixed layer has a lattice adaptation to the at least two photoactive layers due to an adapted Si/C ratio.

5. The photovoltaic tandem cell according to claim 1, wherein the adaptation of the Si/C ratio of the Si/C mixed layer is effected by the reduction in the silicon content and the increase, proportional thereto, in the carbon content as a function of the thickness of the intermediate layer and in the direction from the at least one photoactive layer to the at least one photoactive layer.

6. The photovoltaic tandem cell according to claim 1, wherein the thickness of the at least one intermediate layer is at most 10 μm.

7. The photovoltaic tandem cell according to claim 1, wherein the intermediate layer consists of two Si/C mixed layers.

8. The photovoltaic tandem cell according to claim 1, wherein a silicon layer deposited on a monocrystalline silicon wafer or a silicon wafer which is suitable for solar cells was utilized as substrate.

9. The photovoltaic tandem cell according to claim 1, wherein the thickness of the at least one photoactive layer is at most 50 μm.

10. The photovoltaic tandem cell according to claim 1, wherein at least the n-doped emitter of a first and/or second photoactive layer was formed epitaxially by means of vapour-phase deposition.

11. The photovoltaic tandem cell according to claim 1, wherein the at least one intermediate layer was formed by means of thermal vapour-phase deposition in a temperature range of 800 to 1,400° C. and in a pressure range of 1 mbar to 1 bar.

12. The photovoltaic tandem cell according to claim 1, wherein the at least one photoactive layer was formed by means of vapour-phase deposition in a temperature range of 800 to 1,400° C. and a pressure range of 1 mbar to 1 bar.

13. The photovoltaic tandem cell according to claim 1, wherein the tandem solar cell was contacted electrically on the front- and rear-side via wiring.

14. The photovoltaic tandem cell according to claim 1, wherein the photoactive layers were wired via individual wirings.

15. Method for the production of a photovoltaic tandem cell according to claim 1, comprising depositing at least the n-doped emitter and/or the p-doped region of at least one layer by means of an epitaxial process.

16. The photovoltaic tandem cell according to claim 2, wherein the thickness of the first photoactive layer is at most 40 μm.

17. The photovoltaic tandem cell according to claim 2, wherein the at least one Si/C mixed layer has a lattice adaptation to the at least two photoactive layers due to an adapted Si/C ratio.

18. The photovoltaic tandem cell according to claim 2, wherein the adaptation of the Si/C ratio of the Si/C mixed layer is effected by the reduction in the silicon content and the increase, proportional thereto, in the carbon content as a function of the thickness of the intermediate layer and in the direction from the at least one photoactive layer to the at least one photoactive layer.

19. The photovoltaic tandem cell according to claim 2, wherein the thickness of the at least one intermediate layer is at most 10 μm.

20. The photovoltaic tandem cell according to claim 2, wherein the intermediate layer consists of two Si/C mixed layers.
